(19) United States
(12) Patent Application Publication
(10) Pub. No.: US 2026/0229992 A1
(43) Pub. Date: Aug. 6, 2026

(54) METHOD FOR OPERATING A POWER CONVERTER, POWER CONVERTER CIRCUIT, CONTROLLER AND COMPUTER PROGRAM

(71) Applicant: Infineon Technologies Austria AG, Villach (AT)

(72) Inventors: Guoxing ZHANG, Singapore (SG); Pengcheng BAI, Shenzhen (CN); Zan WANG, Shenzhen (CN)

(21) Appl. No.: 19/377,389

(22) Filed: Nov. 3, 2025

(30) Foreign Application Priority Data
Nov. 5, 2024 (DE) 10 2024132184.9

(51) Int. Cl. H02M 1/44; H02M 1/08; H02M 1/088; H02M 3/335; H03K 17/16

(52) U.S. Cl. CPC H02M 1/44; H02M 1/083; H02M 1/088; H02M 3/33571; H03K 17/166; H03K 2217/0063; H03K 2217/0072

(57) ABSTRACT

A method for operating a power converter comprises: providing an asymmetrical half bridge flyback converter circuit comprising a half bridge with a high side switch and a low side switch and a transformer with a primary winding and a secondary winding, wherein the primary winding is connected to the half bridge and the secondary winding is connected to an output of the power converter, providing a clamping circuit coupled via an auxiliary winding of the transformer to the primary winding, wherein the clamping circuit comprises a third switch and a second diode connected in series, providing a controller configured to switch on and switch off the high and low side switches and the third switch and configured to operate the power converter in a conduction mode.

### RELATED APPLICATIONS

This application claims priority to earlier filed German Patent Application Serial Number 10 2024 132184.9, entitled “METHOD FOR OPERATING A POWER CONVERTER, POWER CONVERTER CIRCUIT, CONTROLLER AND COMPUTER PROGRAM,” filed on Nov. 5, 2024, the entire teachings of which are incorporated herein by this reference.

### TECHNICAL FIELD

The present disclosure relates to a method for operating a power converter, to a power converter circuit, to a controller for use in a power converter and to a computer program for a controller of a power converter circuit.

### BACKGROUND

A power converter, for example a power converter used in a charger application or an adapter application, may for example comprise an asymmetrical half bridge flyback converter circuit. Such an asymmetrical half bridge flyback converter circuit may have one of two possible configurations: the transformer arranged at the high side of the half bridge or the transformer arranged at the low side of the half bridge. Furthermore, an asymmetrical half bridge flyback converter circuit may be operated in different modes of operation which depend on the load connected to the power converter. At lower than maximum loads the converter circuit may be operated in discontinuous conduction mode. This mode of operation comprises a time interval during which both the high side switch and the low side switch of the half bridge are switched off which however means that free oscillations between the magnetizing inductance of the transformer and parasitic capacitances of the converter circuit may happen. These oscillations may cause additional losses and/or electromagnetic interference (EMI) in the power converter. Improved methods for operating a power converter, improved power converter circuits, improved controllers for use in a power converter and improved computer programs for a controller of a power converter circuit may help with solving these and other problems.

### SUMMARY

Certain aspects pertain to a method for operating a power converter, the method comprising: providing an asymmetrical half bridge flyback converter circuit comprising a half bridge with a high side switch and a low side switch and a transformer with a primary winding and a secondary winding, wherein the primary winding is connected to the half bridge and the secondary winding is connected to an output of the power converter, providing a clamping circuit coupled via an auxiliary winding of the transformer to the primary winding, wherein the clamping circuit comprises a third switch and a second diode connected in series, providing a controller configured to switch on and switch off the high and low side switches and the third switch and configured to operate the power converter in a critical conduction mode or in a discontinuous conduction mode, and during a third time interval of the discontinuous conduction mode, switching on the third switch, wherein the high and low side switches are switched off during the third time interval and wherein by switching on the third switch the clamping circuit prevents a free oscillation between a magnetizing inductance of the transformer and parasitic capacitances of the asymmetrical half bridge flyback converter circuit.

Certain aspects pertain to a power converter circuit, comprising: an asymmetrical half bridge flyback converter circuit comprising a half bridge with a high side switch and a low side switch and a transformer with a primary winding and a secondary winding, wherein the primary winding is connected to the half bridge and the secondary winding is connected to an output of the power converter circuit, a clamping circuit coupled via an auxiliary winding of the transformer to the primary winding, wherein the clamping circuit comprises a third switch and a second diode connected in series, and a controller configured to switch on and switch off the high and low side switches and the third switch and configured to operate the power converter circuit in a critical conduction mode or in a discontinuous conduction mode, wherein during a third time interval of the discontinuous conduction mode, the controller switches on the third switch, wherein the high and low side switches are switched off during the third time interval and wherein by switching on the third switch the clamping circuit prevents a free oscillation between a magnetizing inductance of the transformer and parasitic capacitances of the asymmetrical half bridge flyback converter circuit.

Certain aspects pertain to a controller for a power converter circuit, wherein the power converter circuit comprises: an asymmetrical half bridge flyback converter circuit comprising a half bridge with a high side switch and a low side switch and a transformer with a primary winding and a secondary winding, wherein the primary winding is connected to the half bridge and the secondary winding is connected to an output of the power converter circuit, and a clamping circuit coupled via an auxiliary winding of the transformer to the primary winding, wherein the clamping circuit comprises a third switch and a second diode connected in series, wherein the controller is configured to switch on and switch off the high and low side switches and the third switch, wherein the controller is configured to operate the power converter circuit in a critical conduction mode or in a discontinuous conduction mode, and wherein during a third time interval of the discontinuous conduction mode, the controller switches on the third switch, wherein the high and low side switches are switched off during the third time interval and wherein by switching on the third switch the clamping circuit prevents a free oscillation between a magnetizing inductance of the transformer and parasitic capacitances of the asymmetrical half bridge flyback converter circuit.

Certain aspects pertain to computer program comprising instructions which, when the program is executed by a controller of a power converter circuit, cause the controller to switch on and switch off a high side switch, a low side switch and a third switch of the power converter circuit, wherein the power converter circuit comprises an asymmetrical half bridge flyback converter circuit comprising a half bridge with the high side switch and the low side switch and a transformer with a primary winding and a secondary winding, wherein the primary winding is connected to the half bridge and the secondary winding is connected to an output of the power converter circuit and wherein the power converter circuit further comprises a clamping circuit coupled via an auxiliary winding of the transformer to the primary winding, wherein the clamping circuit comprises the third switch and a second diode connected in series, wherein depending on a load connected to the output of the power converter circuit, the computer program causes the controller to operate the power converter circuit in a critical conduction mode or in a discontinuous conduction mode, and wherein during a third time interval of the discontinuous conduction mode, the computer program causes the controller to switch on the third switch, wherein the high and low side switches are switched off during the third time interval and wherein by switching on the third switch the clamping circuit prevents a free oscillation between a magnetizing inductance of the transformer and parasitic capacitances of the asymmetrical half bridge flyback converter circuit.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A and 1B illustrate power converter circuits which each comprise an asymmetrical half bridge flyback converter circuit and a clamping circuit, wherein the clamping circuit is configured to prevent free oscillations between the transformer magnetizing inductance and parasitic capacitances. FIG. 1A shows a power converter circuit with the transformer at the high side of the half bridge and FIG. 1B shows a power converter circuit with the transformer at the low side of the half bridge.

FIGS. 2A and 2B show current and voltage curves of the power converter circuit of FIG. 1A for the case that the circuit is operated in critical conduction mode (FIG. 2A) and for the case that the circuit is operated in discontinuous conduction mode (FIG. 2B). Note that FIG. 2B shows discontinuous conduction mode for the case that the clamping circuit is not used to suppress free oscillations.

FIGS. 3A and 3B show current and voltage curves for discontinuous conduction mode for the case that the clamping circuit is used to prevent free oscillations. FIG. 3A shows the current and voltage curves for operation using peak current control and FIG. 3B shows the current and voltage curves for operation using constant frequency control.

FIGS. 4A and 4B show further power converter circuits which also comprise a power supply circuit connected to the transformer using the same auxiliary winding as the clamping circuit.

FIGS. 5A and 5B show further power converter circuits configured for fixed or constant frequency control, wherein the controller is shown in greater detail, according to a specific example.

FIGS. 6A and 6B show further power converter circuits configured for peak current control, wherein the controller is shown in greater detail, according to a specific example.

FIG. 7 shows a controller configured for use in a power converter circuit, according to an example.

FIG. 8 is a flow chart of a method for operating a power converter, according to an example.

FIG. 9 shows a computer program for a controller of a power converter circuit, according to an example.

### DETAILED DESCRIPTION

In the following detailed description, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

A transistor chip may be manufactured from specific semiconductor material, for example Si. A power transistor chip may for example be manufactured from a semiconductor material like Si, SiC, SiGe, GaAs, GaN, or from any other suitable semiconductor material. A driver chip and a power transistor chip may for example be part of a common power electronic appliance, for example a converter or an inverter. Furthermore, such an appliance may comprise a plurality of driver chips as well as a plurality of power transistor chips which may be electrically connected to form any suitable electrical circuit.

An efficient method for operating a power converter, an efficient power converter circuit, an efficient controller for use in a power converter and an efficient computer program for a controller of a power converter circuit may for example reduce material consumption, ohmic losses, chemical waste, etc. and may thus enable energy and/or resource savings. Improved methods and devices, as specified in this description, may thus at least indirectly contribute to green technology solutions, i.e. climate-friendly solutions providing a mitigation of energy and/or resource use.

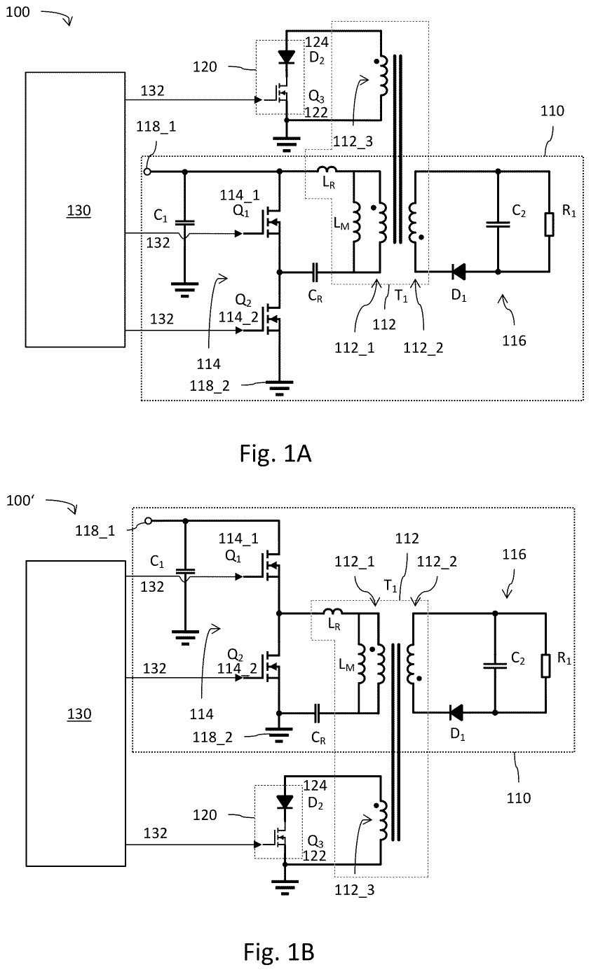

FIGS. 1A and 1B show power converter circuits 100 and 100′ comprising an asymmetrical half bridge flyback converter circuit 110, a clamping circuit 120 and a controller 130. The power converter circuits 100 and 100′ may be similar or identical, except for a position of a transformer T₁, 112. In particular, the power converter circuits 100, 100′ may comprise a half bridge 114 comprising a high side switch Q₁, 114_1 and a low side switch Q2, 114_2. In the power converter circuit 100, the transformer T₁, 112 is arranged at the high side of the half bridge 114 and in the power converter circuit 100′, the transformer T₁, 112 is arranged at the low side of the half bridge 114.

The power converter circuits 100, 100′ may for example be configured for use in DC/DC power converter applications. According to another example, the power converter circuits 100, 100′ are configured for use in AC/DC power converter applications. The power converter circuits 100, 100′ may for example be configured for use in charger applications and/or in power adapter applications or any other suitable applications.

The power converter circuits 100, 100′ may be configured for use in two different modes of operation, depending on the load R₁: at heavy load the power converter circuits 100, 100′ may be operated in critical conduction mode (CRM) and at medium or light load the power converter circuits 100, 100′ may be operated in discontinuous conduction mode (DCM). CRM and DCM are explained in greater detail further below.

The asymmetrical half bridge flyback converter circuit 110 of the power converter circuits 100, 100′ comprises the half bridge 114 with the high side switch Q₁, 114_1 and the low side switch Q₂, 114_2, as well as the transformer 112. The transformer 112 comprises a primary winding 112_1 and a secondary winding 112_2, wherein the primary winding 112_1 is connected to the half bridge 114 and the secondary winding 112_2 is connected to an output of the power converter circuits 100, 100′. The output of the power converter circuits 100, 100′ may for example comprise a rectifier circuit 116 with a first diode D₁ and a capacitor C₂.

The expression “asymmetrical” may refer to the fact that the duty cycles of the two switches 114_1, 114_2 are not equal. Typically, one switch operates with a higher duty cycle than the other. This asymmetry may help with achieving zero voltage switching (ZVS) for one or both of the switches 114_1, 114_2 which may improve the efficiency of the power converter circuits 100, 100′.

According to an example, the primary winding 112_1 and the secondary winding 112_2 of the transformer have opposite polarities. This is indicated in FIGS. 1A and 1B by the dots next to the primary and secondary windings 112_1, 112_2.

According to an example, the asymmetrical half bridge flyback converter circuit 110 may further comprise a first contact 118_1, a second contact 118_2, a resonance capacitor CR, a resonance inductor LR, an input side capacitor C₁ and a rectifier capacitor C₂ and a rectifier diode D₁. The first contact 118_1 may be configured to be connected to any suitable voltage source, for example to a voltage in the range of about 200V to about 400V. The second contact 118_2 may for example be connected to ground potential.

The clamping circuit 120 is coupled to the primary winding 112_1 of the transformer 112 via an auxiliary winding 112_3 of the transformer 112, wherein the auxiliary winding 112_3 is different from the secondary winding 112_2. The clamping circuit 120 comprises a third switch Q₃, 122 and a second diode D₂, 124. The third switch Q₃, 122 and the second diode D₂, 124 are connected in series. According to an example, the auxiliary winding 112_3 has the same polarity as the secondary winding 112_2, i.e. the opposite polarity of the primary winding 112_1.

The controller 130 is configured to control the asymmetrical half bridge flyback converter circuit 110 and the clamping circuit 120. In particular, the controller 130 is configured to switch on and switch off the high and low side switches 114_1, 114_2 and the third switch 122. Furthermore, the controller 130 is configured to operate the power converter circuits 100, 100′ in the critical conduction mode or in the discontinuous conduction mode, depending on the load R₁.

According to an example, the controller 130 comprises or consists of an integrated circuit (IC) chip. The controller 130 may for example comprise or consist of a Si chip. Outputs of the controller 130 may be connected to gate terminals of the first, second and third switches 114_1, 114_2, 122 via controller output connections 132. The controller output connections 132 may for example comprise or consist of bond wires.

The first, second and third switches 114_1, 114_2 and 122 may for example be the same type of switch. According to another example, the third switch 122 may be a type of switch that is different from the first and second switches 114_1, 114_2. The first, second and third switches 114_1, 114_2 and 122 may for example be metal-oxide-semiconductor field-effect transistors (MOSFETs). The first, second and third switches 114_1, 114_2 and 122 may for example be GaN devices or SIC devices. According to an example, each one of the first, second and third switches 114_1, 114_2 and 122 is comprised in an individual semiconductor chip. According to another example, at least two the switches are comprised in a common semiconductor chip.

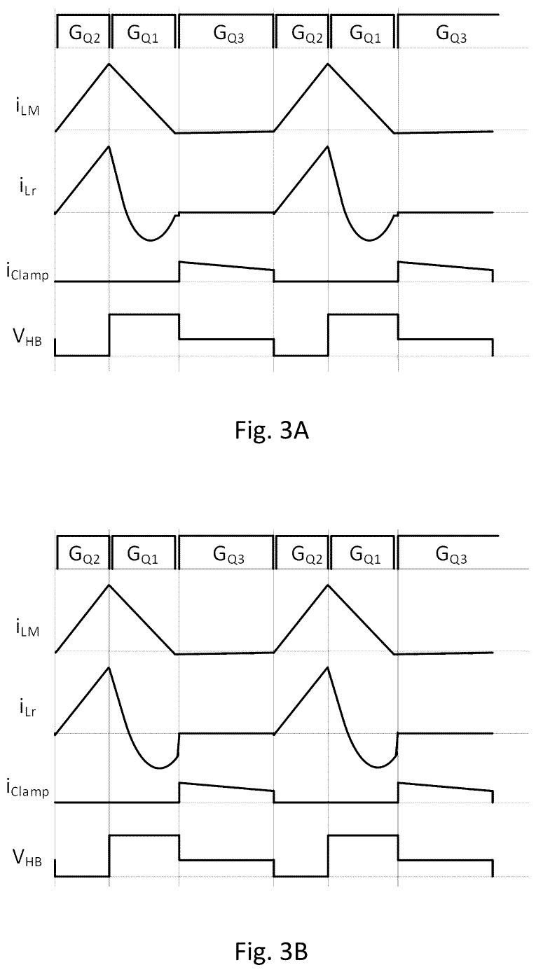

The controller 130 may be configured to operate the power converter circuits 100 and 100′ such that the first, second and third switches 114_1, 114_2 and 122 are switched on at different time intervals, compare also FIGS. 3A and 3B. In particular, the first switch 114_1 may be switched on during a first time interval, the second switch 144_2 may be switched on during a different second time interval and the third switch 122 may be switched on during a further different third time interval. In this control scheme, the respective remaining two switches are switched off during the respective time intervals. That is, the second switch 114_2 and the third switch 122 are switched off during the first time interval, the first and third switch 114_1, 122 are switched off during the second time interval and the first and second switches 114_1, 114_2 are switched off during the third time interval.

The controller 130 is in particular configured to switch on the third switch 122 during the third time interval in the case that the power converter circuits 100 and 100′ are operated in the discontinuous conduction mode. As explained above, the high and low side switches 114_1, 114_2 are switched off during the third time interval. By switching on the third switch 122, the clamping circuit 120 is active and prevents a free oscillation between a magnetizing inductance L_{M} of the transformer 112 and parasitic capacitances of the asymmetrical half bridge flyback converter circuit 110 by electrically shorting the transformer 112.

Furthermore, during the third time interval the clamping circuit 120 may keep the negative magnetizing inductance current freewheeling to achieve zero voltage switching (ZVS) turn-on of the respective first switch in the next switching cycle (Q₂ in FIG. 1A, or Q₁ in FIG. 1B).

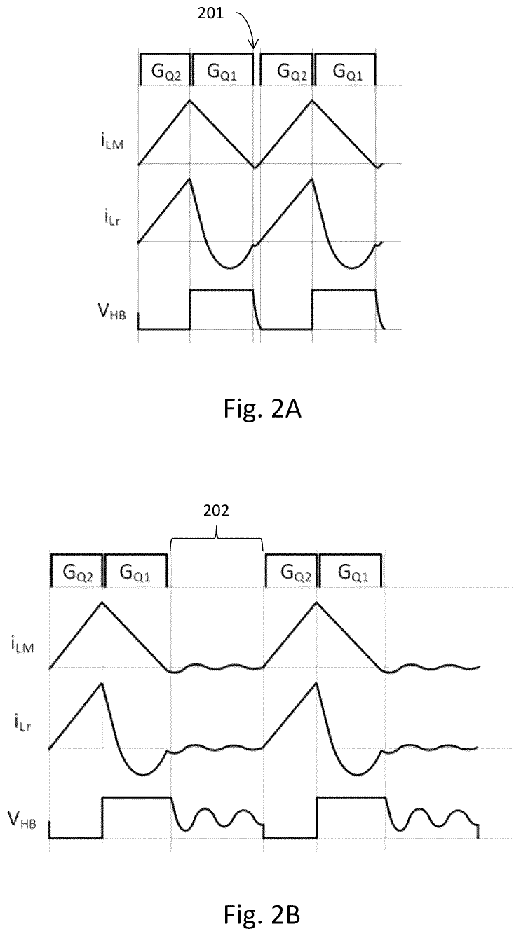

FIG. 2A shows current and voltage curves for the power converter circuit 100 for operation in critical conduction mode (CRM). This mode may be used if a heavy load is connected to the power converter circuit 100. FIG. 2B shows current and voltage curves for the power converter circuit 100 for operation in discontinuous conduction mode (DCM) for the case that the clamping circuit 120 is not used to prevent free oscillations between the magnetizing inductance of the transformer 112 and parasitic capacitances of the power converter circuit 100. DCM may be used if a medium or light load is connected to the power converter circuit 100. Current and voltage curves for the power converter circuit 100′ may be similar.

Note that i_{LM} denotes the current flowing through the magnetizing inductance of the transformer 112, i_{Lr} denotes the current flowing through the primary winding 112_1 and V_{HB} denotes the voltage at the node between the high side switch 114_1 and the low side switch 114_2. G_{Q1} denotes the first time interval during which the high side switch 114_1 is switched on and G_{Q2} denotes the second time interval during which the low side switch 114_2 is switched on.

As shown in FIG. 2A, during CRM operation there is essentially no time delay between switching cycles. This means that when the high side switch 114_1 is switched off at point 201, the low side switch 114_2 is switched on immediately or almost immediately (without significant delay). This means that full power is transferred to the load by the power converter circuit 100.

As shown in FIG. 2B, during DCM operation there is a significant time delay 202 between switching cycles. During the time delay, the high side switch 114_1 and the low side switch 114_2 are switched off. As noted above, FIG. 2B shows the case that the clamping circuit 120 is not used (the third switch 122 remains switched off during the time delay 202). For this reason, i_{LM}, i_{Lr} and V_{HB} show oscillations during the time delay 202. These oscillations may for example cause additional losses and/or electromagnetic interference (EMI) issues and it may therefore be desirable to remove these oscillations. The clamping circuit 120 may be an efficient way to remove these oscillations without requiring the use of high voltage components like a high voltage switch or a high voltage diode. Compared to the use of such high voltage components, the clamping circuit 120 may be a less complex and/or more cost efficient implementation.

FIGS. 3A and 3B show current and voltage curves of the power converter circuit 100 for DCM in the case that the clamping circuit 120 is active. This means that during the third time interval G_{Q3} the third switch 122 is switched on and the clamping circuit 120 is used to short-circuit the transformer 112. For this reason, the magnetizing inductance current i_{LM}, the current flowing through the primary winding i_{Lr} and the voltage V_{HB} do not exhibit oscillations during the third time interval G_{Q3}. This may for example improve the efficiency of the power converter circuit 100. In FIGS. 3A and 3B, i_{Clamp} denotes the current flowing through the clamping circuit 120. The current and voltage curves for the power converter circuit 100′ may essentially be similar to the curves of the power converter circuit 100.

The power converter circuits 100 and 100′ may be operated in DCM using for example two different control strategies: peak current control and constant (or fixed) frequency control. This means that the controller 130 may be configured to control the power converter circuits 100 and 100′ using one or both of these control techniques.

FIG. 3A shows the current and voltage curves for the case that peak current control is used and FIG. 3B shows the current and voltage curves for the case that constant frequency control is used. As is known, peak current control may basically comprise monitoring and controlling the current i_{Lr} flowing through the primary winding 112_1 to achieve regulation. The basic idea is to sense the peak inductor current in each switching cycle and compare it to a reference value. When the inductor current reaches the reference peak value, the power switch Q₁ or Q₂ is turned off. As is also known, constant frequency control on the other hand may involve regulating the output voltage by adjusting the duty cycle of the switching signals while maintaining a fixed (constant) switching frequency.

In DCM conditions, the controller 130 keeps the third switch 122 switched on during the third time interval G_{Q3}. At the end of the third time interval, the third switch 122 is switched off again. This causes the current i_{clamp} to flow through the clamping circuit 120 during the third time interval G_{Q3}. The current i_{clamp} decreases in strength over the third time interval G_{Q3} because it is driven by the energy stored in the asymmetrical half bridge flyback converter circuit 110.

As shown in FIGS. 3A and 3B, the magnetizing inductance current ILM may be (slightly) negative at the end of the first time period G_{Q1} when Q₁ is switched off. Using the clamping circuit 120, the negative current i_{LM} can be transferred to the auxiliary winding 112_3. Since the voltage drop of the diode 124 and the third switch 122 in the clamping circuit 120 may be comparatively small, the negative current i_{LM} may be used for zero voltage switching (ZVS) turn-on of Q₁ in the next switching cycle, according to an example.

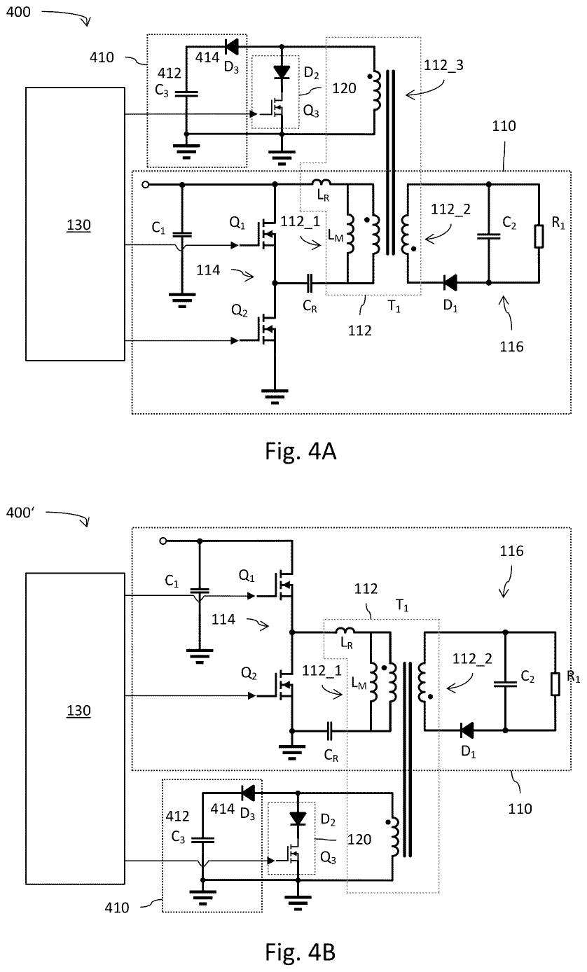

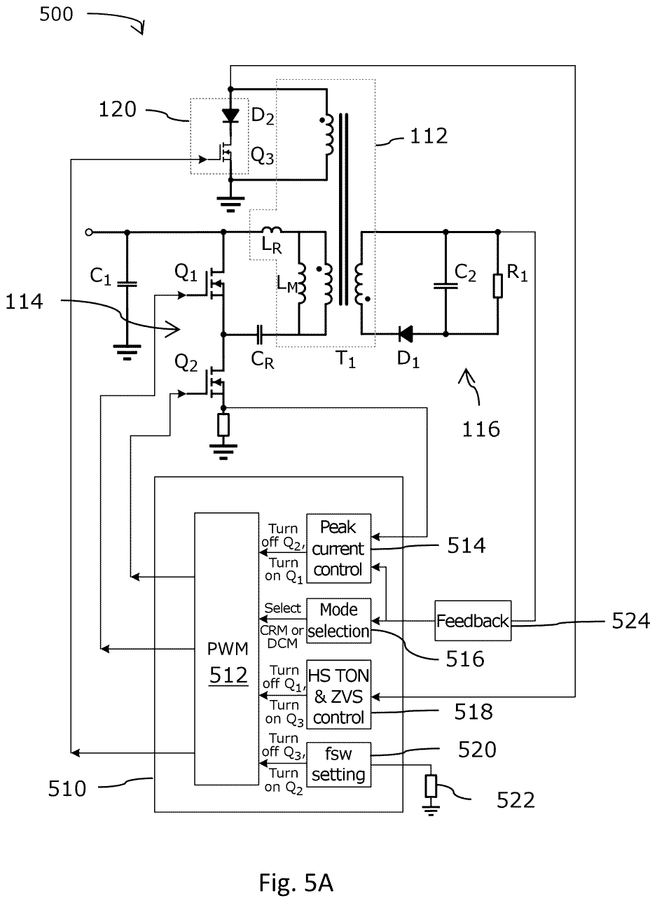

FIG. 4A shows a power converter circuit 400 which may be similar or identical to the power converter circuit 100, except for the differences described in the following. Similarly, FIG. 4B shows a power converter circuit 400′ which may be similar or identical to the power converter circuit 100′, except for the differences described in the following.

In particular, the power converter circuits 400 and 400′, may comprise all components described with respect to the power converter circuits 100 and 100′. However, the power converter circuits 400 and 400′ additionally comprise a power supply circuit 410. The power supply circuit 410 is configured to provide power for the controller 130. The power supply circuit 410 may for example comprise a third capacitor C₃, 412 and a third diode D₃, 414 connected in series. Furthermore, the power supply circuit 410 is connected to the auxiliary winding 112_3 and via the auxiliary winding 112_3 to the asymmetrical half bridge flyback converter circuit 110.

Combining the clamping circuit 120 and the power supply circuit on the auxiliary winding 112_3 may for example reduce the complexity of the power converter circuits 400 and 400′ and may therefore reduce e.g. fabrication time and/or costs.

In the case of the power converter circuit 400 (where the transformer 112 is arranged at the high side of the half bridge 114), the auxiliary winding 112_3 can be used for V_{CC} supply when Q₁ is switched on and Q₃ is switched off as well as for DCM ringing clamping when Q₃ is switched on and Q₁ is switched off.

In the case of the power converter circuit 400′ (where the transformer 112 is arranged at the low side of the half bridge 114), the auxiliary winding 112_3 can be used for V_{CC} supply when Q₂ is switched on and Q₃ is switched off as well as for DCM ringing clamping when Q₃ is switched on and Q₁ is switched off.

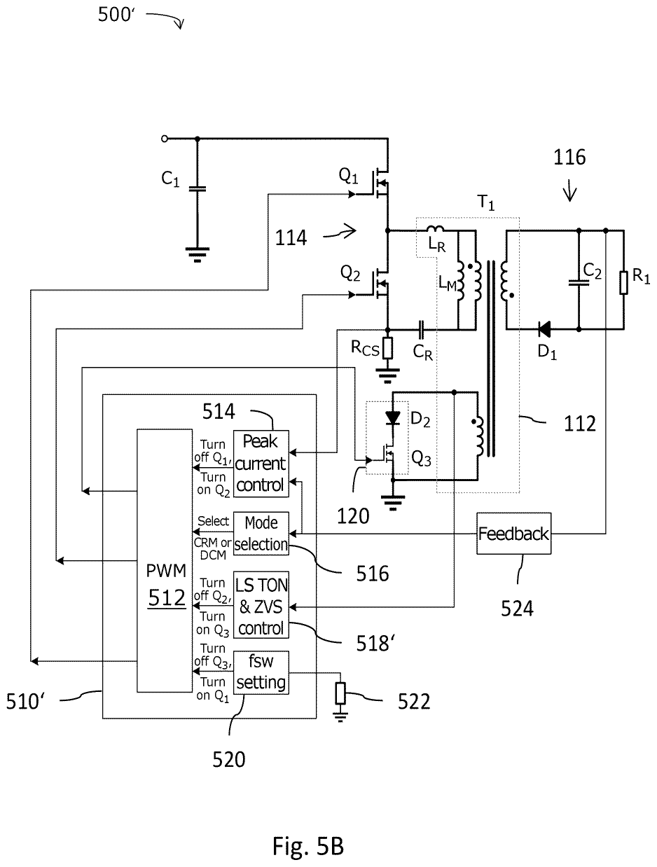

FIG. 5A shows a further power converter circuit 500 which may be similar or identical to the power converter circuits 100 and 400, except for the differences described in the following. FIG. 5B shows a further power converter circuit 500′ which may be similar or identical to the power converter circuits 100′ and 400′, except for the differences described in the following. The power converter circuits 500 and 500′ are configured to be operated using constant frequency control (i.e. regulating the output voltage by adjusting the duty cycle of the switching signals while maintaining a fixed switching frequency).

As shown, the power converter circuits 500 and 500′ comprises the components described with respect to the power converter circuits 100, respectively 100′. However, the power converter circuits 500 and 500′ may also comprise the power supply circuit 410 disclosed with respect to the power converter circuits 400 and 400′.

The example of the power converter circuit 500 shown in FIG. 5A in particular comprises a controller 510 which is a specific and more detailed example of the controller 130. The controller 510 comprises a pulse width modulator 512, a peak current control part 514, a mode selector 516 (configured to select DCM or CRM), a high side turn-on and ZVS controller 518 and a frequency setting part 520. The pulse width modulator 512 is configured to output pulse width modulated signals to the gates of the switches Q₁, Q₂ and Q₃ based on input received from the peak current control part 514, the mode selector 516, the high side turn-on and ZVS controller 518 and the frequency setting part 520. A feedback voltage provided to the peak current control part 514 and the mode selector 516 via feedback loop 524 is used to determine the operation mode (CRM, DCM, or burst mode) of the power converter circuit 500. An input of the high side turn-on and ZVS controller 518 is connected to the clamping circuit 120.

Under DCM, the peak current control part 514 is configured to receive information of magnetizing current and feedback voltage to determine the turn-off time of the switch Q₂ and the turn-on time of the switch Q₁. The high side turn-on and ZVS controller 518 is configured to manage the turn-on time of the switch Q₁. The switching frequency under DCM is set by an external component, i.e. a resistor or a capacitor via the frequency setting part 520 (in the example of FIG. 5A, an external resistor 522 is used). After the switch Q₁ is turned off, the switch Q₃ is turned on and will be turned off again based on the frequency setting.

The power converter circuit 500′ of FIG. 5B has the transformer 112 arranged at the low side of the half bridge 114, similar to the power converter circuits 100′ and 400′. The controller 510′ of the power converter circuit 500′ may be similar or identical to the controller 510 of the power converter circuit 500, except that a low side turn-on and ZVS controller 518′ replaces the high side turn-on and ZVS controller 518.

Under DCM, the peak current control part 514 of controller 510′ is configured to receive information of magnetizing current and feedback voltage to determine the turn-off time of the switch Q₁ and the turn-on time of the switch Q₂. The low side turn-on and ZVS controller 518′ is configured to manage the turn-on time of the switch Q₂. The frequency under DCM is set by an external component, i.e. a resistor or a capacitor via the frequency setting part 520 (in the example of FIG. 5A, an external resistor 522 is used). After the switch Q₂ is turned off, the switch Q₃ is turned on and will be turned off again based on the frequency setting.

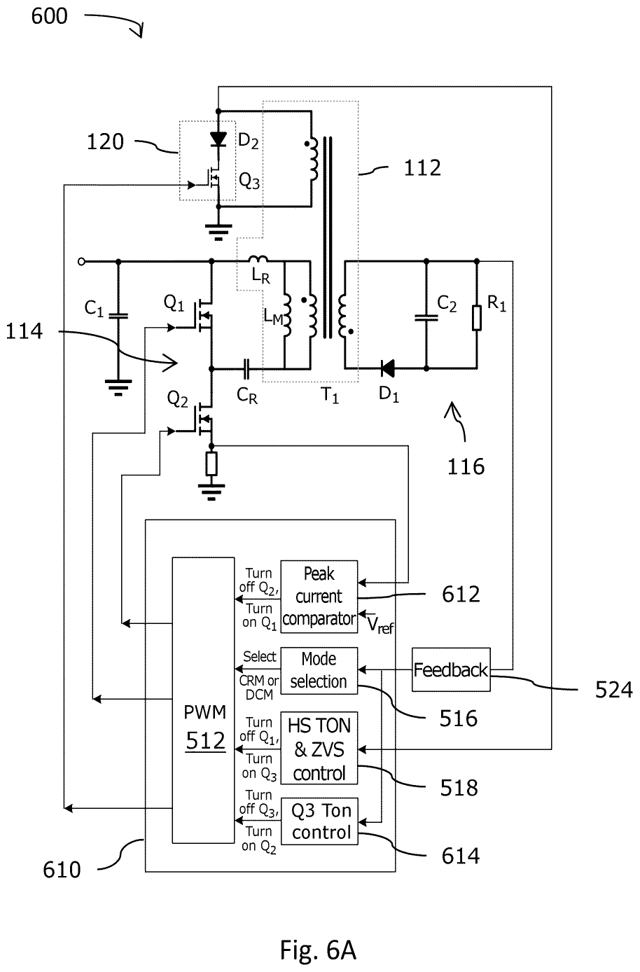

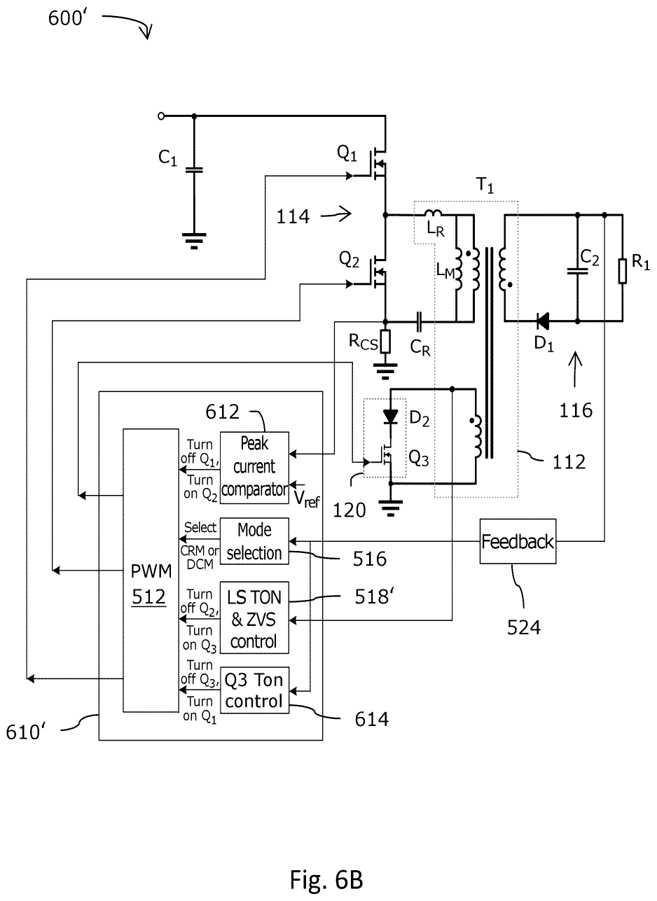

FIGS. 6A and 6B show further power converter circuits 600 and 600′ which may be similar or identical to the power converter circuits 500 and 500′, respectively. However, the power converter circuits 600 and 600′ are configured to be operated using constant frequency control (i.e. monitoring and controlling the current flowing through the primary winding of the transformer 112 to achieve regulation). The controller 610 of the power converter circuit 600 may be similar or identical to the controller 510, except that the peak current control part 514 is replaced by a peak current comparator 612 and the frequency setting part 520 is replaced by a Q₃ turn-on controller 614. An input of the peak current comparator 612 is connected to the source of the the switch Q₂ and the peak current comparator 612 is configured to compare a detected current against a reference signal v_{ref}. An input of the Q₃ turn-on controller 614 is connected to the feedback 524.

In this example controller 610, a feedback voltage provided via the feedback 524 is used to determine the operation mode (i.e. CRM, DCM, or burst mode). In the case of DCM, the peak current comparator 612 is configured to compare the sensed magnetizing current with the reference signal v_{ref} to turn off the switch Q₂ and to turn on the switch Q₁. The high side turn-on and ZVS controller 518 is configured to manage the turn-on time of the switch Q₁. Q₃ is turned on by the Q₃ turn-on controller 614 once Q₁ is turned off and its turn-on time is based on the feedback voltage provided via feedback 524.

In the power converter circuit 600′, the controller 610 is replaced by the controller 610′. The controller 610′ may be similar or identical to the controller 610, except that the high side turn-on and ZVS controller 518 is replaced by the low side turn-on and ZVS controller 518′. The peak current comparator 612 is configured to compare the sensed magnetizing current with the reference signal v_{ref} to turn off the switch Q₁ and to turn on the switch Q₂. The low side turn-on and ZVS controller 518′ is configured to manage the turn-on time of the switch Q₂. Q₃ is turned on by the Q₃ turn-on controller 614 once Q₂ is turned off and its turn-on time is based on the feedback voltage provided via feedback 524.

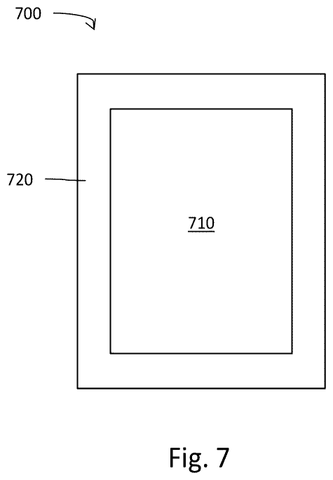

FIG. 7 shows a controller 700 configured for use in a power converter circuit. The controller 700 may for example be used in any of the power converter circuits 100 to 600′. The controller 700 may in particular be similar or identical to the controller 130 or any of the controllers 510 to 610′.

According to an example, the controller 700 comprises an integrated circuit chip 710. The integrated circuit chip 710 may for example comprise or consist of Si. Furthermore, the controller 700 may comprise an encapsulation 720 encapsulating the integrated circuit chip 710, wherein the encapsulation 720 comprises or consists of e.g. a molded body. The controller 700 may for example be configured to be arranged on and electrically connected to a printed circuit board (PCB).

The controller 700 may be configured to control an asymmetrical half bridge flyback converter circuit and a clamping circuit as described above with respect to the FIGS. 1 to 6B. The controller 700 may in particular be configured to control the clamping circuit in order to prevent free oscillation between a magnetizing inductance of the transformer and parasitic capacitances of the asymmetrical half bridge flyback converter circuit as outlined above with respect to FIGS. 1 to 6B.

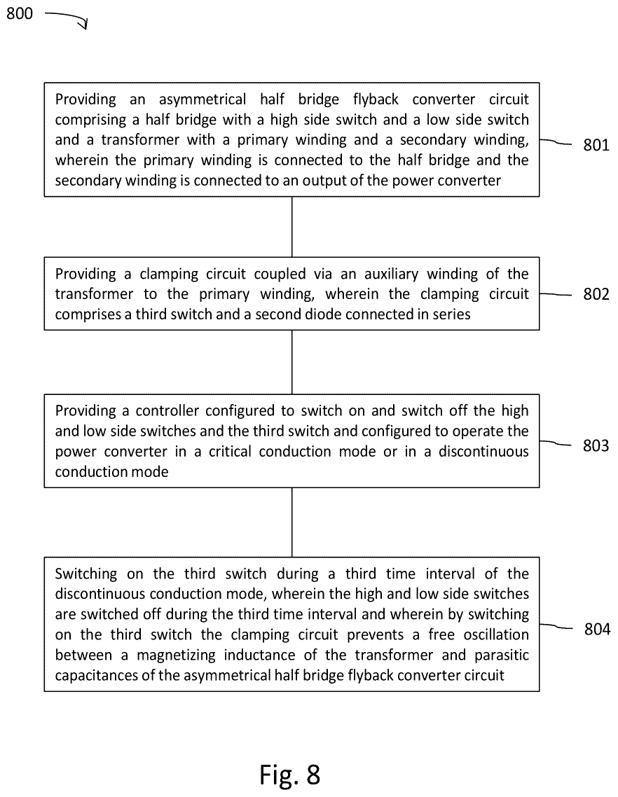

FIG. 8 is a flow chart of an exemplary method 800 for operating a power converter. The method 800 may for example be performed using any of the power converter circuits 100 to 600′.

The method 800 comprises at 801 a process of providing an asymmetrical half bridge flyback converter circuit comprising a half bridge with a high side switch and a low side switch and a transformer with a primary winding and a secondary winding, wherein the primary winding is connected to the half bridge and the secondary winding is connected to an output of the power converter; at 802 a process of providing a clamping circuit coupled via an auxiliary winding of the transformer to the primary winding, wherein the clamping circuit comprises a third switch and a second diode connected in series; at 803 a process of providing a controller configured to switch on and switch off the high and low side switches and the third switch and configured to operate the power converter in a critical conduction mode or in a discontinuous conduction mode; and at 804 a process of switching on the third switch during a third time interval of the discontinuous conduction mode, wherein the high and low side switches are switched off during the third time interval and wherein by switching on the third switch the clamping circuit prevents a free oscillation between a magnetizing inductance of the transformer and parasitic capacitances of the asymmetrical half bridge flyback converter circuit.

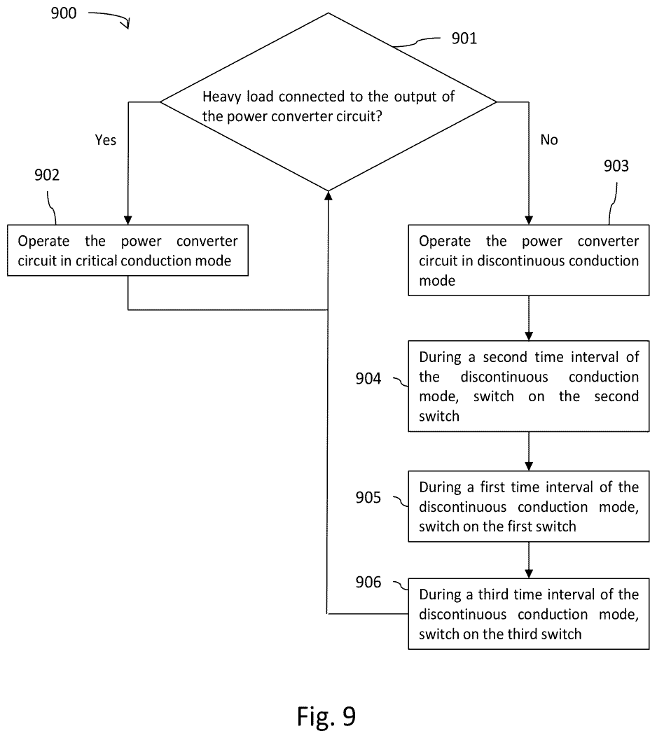

FIG. 9 shows an exemplary computer program 900 comprising instructions which, when the program 900 is executed by a controller of a power converter circuit, cause the controller to switch on and switch off a high side switch, a low side switch and a third switch of the power converter circuit. The program 900 may for example be performed using the controllers 130 to 610′.

At 901 the program 900 comprises a step of checking whether a heavy load connected to the output of a power converter circuit. If this is the case, the controller will operate the power converter circuit in critical conduction mode as shown at 902. If instead a medium or light load is connected to the output, the controller will operate the power converter circuit in discontinuous conduction mode, as shown at 903. Discontinuous conduction mode comprises switching on a second switch during a second time interval at 904, switching on a first switch during a first time interval at 905 and switching on a third switch during a third time interval at 906.

### EXAMPLES

In the following, the method for operating a power converter, the power converter circuit, the controller for a power converter circuit and the computer program are further explained using specific examples.

Example 1 is a method for operating a power converter, the method comprising: providing an asymmetrical half bridge flyback converter circuit comprising a half bridge with a high side switch and a low side switch and a transformer with a primary winding and a secondary winding, wherein the primary winding is connected to the half bridge and the secondary winding is connected to an output of the power converter, providing a clamping circuit coupled via an auxiliary winding of the transformer to the primary winding, wherein the clamping circuit comprises a third switch and a second diode connected in series, providing a controller configured to switch on and switch off the high and low side switches and the third switch and configured to operate the power converter in a critical conduction mode or in a discontinuous conduction mode, and during a third time interval of the discontinuous conduction mode, switching on the third switch, wherein the high and low side switches are switched off during the third time interval and wherein by switching on the third switch the clamping circuit prevents a free oscillation between a magnetizing inductance of the transformer and parasitic capacitances of the asymmetrical half bridge flyback converter circuit.

Example 2 is the method of example 1, wherein the transformer is arranged at a high side of the half bridge.

Example 3 is the method of example 1, wherein the transformer is arranged at a low side of the half bridge.

Example 4 is the method of one of the preceding examples, further comprising: a power supply circuit for the controller, the power supply circuit comprising a third capacitor and a third diode connected in series, wherein the power supply circuit is connected to the auxiliary winding.

Example 5 is the method of one of the preceding examples, wherein the primary winding and the secondary winding have opposite polarities.

Example 6 is the method of example 5, wherein the auxiliary winding has the same polarity as the secondary winding.

Example 7 is the method of one of the preceding examples, wherein during the discontinuous conduction mode the controller is configured to adjust an output power of the power converter using a first control mode or a second control mode, wherein the first control mode comprises keeping a peak value of a magnetizing current of the transformer constant and adjusting a duration of the third time interval, and wherein the second control mode comprises keeping a switching frequency of the half bridge constant and adjusting the peak value of the magnetizing current.

Example 8 is a power converter circuit, comprising: an asymmetrical half bridge flyback converter circuit comprising a half bridge with a high side switch and a low side switch and a transformer with a primary winding and a secondary winding, wherein the primary winding is connected to the half bridge and the secondary winding is connected to an output of the power converter circuit, a clamping circuit coupled via an auxiliary winding of the transformer to the primary winding, wherein the clamping circuit comprises a third switch and a second diode connected in series, and a controller configured to switch on and switch off the high and low side switches and the third switch and configured to operate the power converter circuit in a critical conduction mode or in a discontinuous conduction mode, wherein during a third time interval of the discontinuous conduction mode, the controller switches on the third switch, wherein the high and low side switches are switched off during the third time interval and wherein by switching on the third switch the clamping circuit prevents a free oscillation between a magnetizing inductance of the transformer and parasitic capacitances of the asymmetrical half bridge flyback converter circuit.

Example 9 is the power converter circuit of example 8, wherein the high side switch, the low side switch and the third switch are the same type of switch.

Example 10 is the power converter circuit of example 8 or 9, wherein the primary winding and the secondary winding have opposite polarities.

Example 11 is the power converter circuit of one of examples 8 to 10, further comprising: a power supply circuit for the controller, the power supply circuit comprising a third capacitor and a third diode connected in series, wherein the power supply circuit is connected to the auxiliary winding.

Example 12 is the power converter circuit of one of examples 8 to 11, wherein during the discontinuous conduction mode the controller is configured to adjust an output power of the power converter circuit using a first control mode or a second control mode, wherein the first control mode comprises keeping a peak value of a magnetizing current of the transformer constant and adjusting a duration of the third time interval, and wherein the second control mode comprises keeping a switching frequency of the half bridge constant and adjusting the peak value of the magnetizing current.

Example 13 is a controller for a power converter circuit, wherein the power converter circuit comprises: an asymmetrical half bridge flyback converter circuit comprising a half bridge with a high side switch and a low side switch and a transformer with a primary winding and a secondary winding, wherein the primary winding is connected to the half bridge and the secondary winding is connected to an output of the power converter circuit, and a clamping circuit coupled via an auxiliary winding of the transformer to the primary winding, wherein the clamping circuit comprises a third switch and a second diode connected in series, wherein the controller is configured to switch on and switch off the high and low side switches and the third switch, wherein the controller is configured to operate the power converter circuit in a critical conduction mode or in a discontinuous conduction mode, and wherein during a third time interval of the discontinuous conduction mode, the controller switches on the third switch, wherein the high and low side switches are switched off during the third time interval and wherein by switching on the third switch the clamping circuit prevents a free oscillation between a magnetizing inductance of the transformer and parasitic capacitances of the asymmetrical half bridge flyback converter circuit.

Example 14 is the controller of example 13, wherein the controller comprises or consists of an integrated circuit chip.

Example 15 is a computer program comprising instructions which, when the program is executed by a controller of a power converter circuit, cause the controller to switch on and switch off a high side switch, a low side switch and a third switch of the power converter circuit, wherein the power converter circuit comprises an asymmetrical half bridge flyback converter circuit comprising a half bridge with the high side switch and the low side switch and a transformer with a primary winding and a secondary winding, wherein the primary winding is connected to the half bridge and the secondary winding is connected to an output of the power converter circuit and wherein the power converter circuit further comprises a clamping circuit coupled via an auxiliary winding of the transformer to the primary winding, wherein the clamping circuit comprises the third switch and a second diode connected in series, wherein depending on a load connected to the output of the power converter circuit, the computer program causes the controller to operate the power converter circuit in a critical conduction mode or in a discontinuous conduction mode, and wherein during a third time interval of the discontinuous conduction mode, the computer program causes the controller to switch on the third switch, wherein the high and low side switches are switched off during the third time interval and wherein by switching on the third switch the clamping circuit prevents a free oscillation between a magnetizing inductance of the transformer and parasitic capacitances of the asymmetrical half bridge flyback converter circuit.

Example 16 is an apparatus comprising means for performing the method according to anyone of examples 1 to 7.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

1. A method for operating a power converter, the method comprising:
providing an asymmetrical half bridge flyback converter circuit comprising a half bridge with a high side switch and a low side switch and a transformer with a primary winding and a secondary winding, wherein the primary winding is connected to the half bridge and the secondary winding is connected to an output of the power converter,
providing a clamping circuit coupled via an auxiliary winding of the transformer to the primary winding, wherein the clamping circuit comprises a third switch and a second diode connected in series,
providing a controller configured to switch on and switch off the high and low side switches and the third switch and configured to operate the power converter in a critical conduction mode or in a discontinuous conduction mode, and
during a third time interval of the discontinuous conduction mode, switching on the third switch, wherein the high and low side switches are switched off during the third time interval and wherein by switching on the third switch the clamping circuit prevents a free oscillation between a magnetizing inductance of the transformer and parasitic capacitances of the asymmetrical half bridge flyback converter circuit.

2. The method of claim 1, wherein the transformer is arranged at a high side of the half bridge.

3. The method of claim 1, wherein the transformer is arranged at a low side of the half bridge.

4. The method of claim 1, further comprising: a power supply circuit for the controller, the power supply circuit comprising a third capacitor and a third diode connected in series,
wherein the power supply circuit is connected to the auxiliary winding.

5. The method of claim 1, wherein the primary winding and the secondary winding have opposite polarities.

6. The method of claim 5, wherein the auxiliary winding has the same polarity as the secondary winding.

7. The method of claim 1, wherein during the discontinuous conduction mode the controller is configured to adjust an output power of the power converter using a first control mode or a second control mode,
wherein the first control mode comprises keeping a peak value of a magnetizing current of the transformer constant and adjusting a duration of the third time interval, and
wherein the second control mode comprises keeping a switching frequency of the half bridge constant and adjusting the peak value of the magnetizing current.

8. A power converter circuit, comprising:
an asymmetrical half bridge flyback converter circuit comprising a half bridge with a high side switch and a low side switch and a transformer with a primary winding and a secondary winding, wherein the primary winding is connected to the half bridge and the secondary winding is connected to an output of the power converter circuit,
a clamping circuit coupled via an auxiliary winding of the transformer to the primary winding, wherein the clamping circuit comprises a third switch and a second diode connected in series, and
a controller configured to switch on and switch off the high and low side switches and the third switch and configured to operate the power converter circuit in a critical conduction mode or in a discontinuous conduction mode,
wherein during a third time interval of the discontinuous conduction mode, the controller switches on the third switch, wherein the high and low side switches are switched off during the third time interval and wherein by switching on the third switch the clamping circuit prevents a free oscillation between a magnetizing inductance of the transformer and parasitic capacitances of the asymmetrical half bridge flyback converter circuit.

9. The power converter circuit of claim 8, wherein the high side switch, the low side switch and the third switch are the same type of switch.

10. The power converter circuit of claim 8, wherein the primary winding and the secondary winding have opposite polarities.

11. The power converter circuit claim 8, further comprising: a power supply circuit for the controller, the power supply circuit comprising a third capacitor and a third diode connected in series,
wherein the power supply circuit is connected to the auxiliary winding.

12. The power converter circuit of claim 8, wherein during the discontinuous conduction mode the controller is configured to adjust an output power of the power converter circuit using a first control mode or a second control mode,
wherein the first control mode comprises keeping a peak value of a magnetizing current of the transformer constant and adjusting a duration of the third time interval, and
wherein the second control mode comprises keeping a switching frequency of the half bridge constant and adjusting the peak value of the magnetizing current.

13. A controller for a power converter circuit, wherein the power converter circuit comprises:
an asymmetrical half bridge flyback converter circuit comprising a half bridge with a high side switch and a low side switch and a transformer with a primary winding and a secondary winding, wherein the primary winding is connected to the half bridge and the secondary winding is connected to an output of the power converter circuit, and
a clamping circuit coupled via an auxiliary winding of the transformer to the primary winding, wherein the clamping circuit comprises a third switch and a second diode connected in series,
wherein the controller is configured to switch on and switch off the high and low side switches and the third switch,
wherein the controller is configured to operate the power converter circuit in a critical conduction mode or in a discontinuous conduction mode, and
wherein during a third time interval of the discontinuous conduction mode, the controller switches on the third switch, wherein the high and low side switches are switched off during the third time interval and wherein by switching on the third switch the clamping circuit prevents a free oscillation between a magnetizing inductance of the transformer and parasitic capacitances of the asymmetrical half bridge flyback converter circuit.

14. The controller of claim 13, wherein the controller comprises or consists of an integrated circuit chip.

15. (canceled)
